(19) United States
(12) Patent Application Publication
(10) Pub. No.: US 2014/0370632 A1
(43) Pub. Date: Dec. 18, 2014

(54) TFT AND LCD PANEL AND METHOD FOR MANUFACTURING THE SAME

(71) Applicant: SHENZHEN CHINA STAR OPTOELECTRONICS TECHNOLOGY CO., LTD., Shenzhen (CN)

(72) Inventors: Chenghung CHEN, Shenzhen (CN); Chengming HE, Shenzhen (CN)

(21) Appl. No.: 14/473,290

(22) Filed: Aug. 29, 2014

Related U.S. Application Data
(62) Division of application No. 13/000,920, filed on Dec. 22, 2010.

(30) Foreign Application Priority Data
Nov. 26, 2010 (CN) 201010564412.X

(51) Int. Cl. H01L 27/12

(52) U.S. Cl. CPC H01L 27/1259; H01L 27/127
USPC 438/34

(57) ABSTRACT

The present invention discloses a TFT, an LCD panel and method for manufacturing the same. In the LCD panel, a transparent conducting layer forms a first electrode of a TFT and a second electrode of a TFT directly, and the transparent conducting layer also serves as a connecting line between a TFT and a data line and between a TFT and an LC capacitor. So it is not necessary to form a via hole over the TFT to link the TFT and the transparent conducting layer. In this way, an area of a pixel electrode can be further extended, and the aperture rate of an LCD panel can be also increased, raising a transmittance of light from light sources passing through the pixel electrode In this way, not only a design in pixels becomes more flexible but also the aperture rate of an LCD panel becomes higher.

### CROSS-REFERENCES TO RELATED APPLICATION

This application is a divisional application of U.S. application Ser. No. 13/000,920, filed on Dec. 22, 2010 and entitled “TFT and LCD Panel and Method for Manufacturing the Same.”

### BACKGROUND OF THE INVENTION

1. Field of the Invention

The present invention relates to a liquid crystal display (LCD) panel, and more particularly, to a thin-film transistor (TFT), an LCD panel and method for manufacturing the same where a transparent conducting layer is directly connected to a data line and a switch unit.

2. Description of Prior Art

An advanced monitor with multiple functions is an important feature for use in current consumer electronic products. Liquid crystal displays (LCDs) which are colorful monitors with high resolution are widely used in various electronic products such as monitors for mobile phones, personal digital assistants (PDAs), digital cameras, laptop computers, and notebook computers.

An LCD panel of a conventional LCD comprises a plurality of pixels. Each pixel comprises three pixel units representing the three primary colors of light—Red (R), Green (G), and Blue (B). Referring to FIG. 1 showing a schematic diagram of a pixel unit 10 of a conventional LCD panel, when a gate driver (not shown) outputs a scan signal through scan line 11 to activate each thin film transistor (TFT) of the pixel units 10 in each row in sequence, a source driver outputs corresponding data signals through data lines 12 to the pixel units in a straight row. The pixel units 10 are charged to obtain required voltage and display different gray levels. The gate driver outputs a scan signal row by row to turn on each TFT 13 of the pixel units in each row. Then, the source driver charges/discharges the turned-on pixel units in each row. Based on this sequence, all of the pixel units 10 on the LCD panel are charged. After all of the pixel units are completely charged, the pixel units 10 in the first row start to be charged again.

Refer to FIG. 2 and FIG. 1 simultaneously. FIG. 2 is a cross section view along a line from point A to point B to point C in FIG. 1. As FIG. 2 shows, between point A and point B, a gate 131 of a TFT 13 is formed by a first metal layer, and a source 132 and a drain 133 of a TFT 13 are formed by a second metal layer. A bottom electrode plate 141 of a storage capacitor Cst is also formed by a first metal layer between point B and point C. A transparent conducting layer 15 between the TFT 13 and the storage capacitor Cst serves as a pixel electrode.

Please refer to FIGS. 3 to 7, which illustrate diagrams of the manufacturing process for completing the structure shown in FIG. 2. Each of the figures represents a mask process. In other words, it requires five mask processes to complete the structure illustrated in FIG. 2.

Refer to FIG. 3. During this stage of the manufacturing process, the first metal layer (not shown) is deposited on a glass substrate 101. Meanwhile, a developing process is conducted through a first mask. The developing process contains the following steps: coating a photoresist (not shown) on the first metal layer, exposing the photoresist through the first mask having a specific pattern, and then washing out the exposed photoresist with a developer. Afterwards, the first metal layer undergoes an etching process. The etching process includes the steps of: removing the first metal layer which is not covered by the photoresist by using strong acid, forming a bottom electrode plate 141 used as the gate 131 and the storage capacitor Cst of the TFT 13 as shown in FIG. 3 by reserving the first metal layer covered by the photoresist (roughly showing the specific pattern), and washing out the remaining photoresist.

Refer to FIG. 4. During this stage of the manufacturing process, firstly, an isolation layer 16 is deposited. Secondly, an active layer 17 is deposited. thirdly, an n+ layer 18 are deposited. Finally, a developing process is conducted through a second mask. Meanwhile, the active layer 17 and the ohmic contact layer 18 undergo an etching process.

Refer to FIG. 5. During this stage of the manufacturing process, firstly, the second metal layer (not shown) is deposited. Next, a developing process is conducted through a third mask. Meanwhile, the second metal layer and the ohmic contact layer 18 undergo an etching process to form the drain 132 and the source 133 of the TFT 13 and a data line 12.

Refer to FIG. 6. During this stage of the manufacturing process, firstly, a passivation layer 19 is deposited. Next, a developing process is conducted through a fourth mask. Meanwhile, the passivation layer 19 undergoes an etching process in order to form a via 20 on top of the source 133.

At last, refer to FIG. 7. During this stage of the manufacturing process, firstly, the transparent conducting layer 15 is deposited. Next, a developing process is conducted through a fifth mask. Meanwhile, transparent conducting layer 15 undergoes an etching process in order to form a structure as shown in FIG. 7. The basic structure of the LCD panel 10 up to here is complete.

However, the structure of the LCD panel 10 and its related process technology still has room to improve. For instance, an increase in an aperture rate of the pixel is necessary to increase the overall transmittance of a panel.

### SUMMARY OF THE INVENTION

An objective of the present invention is to provide a method of forming a liquid crystal display (LCD) panel, an LCD panel and a thin film transistor thereof to raising an aperture ratio of the LCD panel to improve a transmittance of the LCD panel.

In one aspect of the present invention, a method of forming a liquid crystal display (LCD) panel comprises: a glass substrate is provided; a first metal layer formed on the glass substrate is etched to form a data line; a first passivation layer and a second metal layer are deposited on the glass substrate and on the first metal layer in order; the second metal layer is etched to form a control electrode of a switch unit; an isolation layer and an active layer are deposited on the first passivation layer and on the second metal layer in order; the active layer is etched simultaneously for reserving the active layer above the control electrode, and the active layer serves as a channel of the switch unit; the first passivation layer and the isolation layer above the data line are etched to form a via hole on top of the data line; a transparent conducting layer is deposited on the isolation layer, the data line, and the active layer; and the transparent conducting layer is etched to divide the transparent conducting layer into a first transparent conducting layer and a second transparent conducting layer, wherein the data line is electrically connected to the active layer through the first transparent conducting layer on the via hole, and the active layer is electrically connected to the second transparent conducting layer.

In another aspect of the present invention, an LCD panel comprises: a glass substrate; a first metal layer, disposed on the glass substrate, for forming a data line; a first passivation layer, disposed on the glass substrate and on the first metal layer; a second metal layer, disposed on the first passivation layer, for forming a control electrode of a switch unit; an isolation layer, disposed on the first passivation layer and the second metal layer; an active layer, disposed on the isolation layer, for functioning as a channel of the switch unit; a via hole, formed on top of the data line; and a transparent conducting layer, disposed on the isolation layer and on the via hole, comprising a first transparent conducting layer and a second transparent conducting layer, the first transparent conducting layer electrically connected to the data line, the second transparent conducting layer functioning as a pixel electrode. Upon receiving a scan voltage by the control electrode, a data voltage from the data line is transmitted to the second transparent conducting layer through the first transparent conducting layer and the active layer.

In still another aspect of the present invention, a transistor formed on a glass substrate comprises: a first passivation layer disposed on the glass substrate; a metal layer disposed on the first passivation layer and the substrate, for forming a gate of the transistor; an isolation layer, disposed on the metal layer; an active layer, disposed on the isolation layer, for functioning as a channel of the transistor; and a transparent conducting layer with an opening thereon to divide a first transparent conducting layer and a second transparent conducting layer. The first transparent conducting layer functions as a first electrode for inputting or outputting an electrical signal while the second transparent conducting layer functions as a second electrode for inputting or outputting the electrical signal.

In still another aspect of the present invention, a method of forming a liquid crystal display (LCD) panel comprises: a glass substrate is provided; a first metal layer formed on the glass substrate is etched to form a control electrode of a switch unit; a first passivation layer and a second metal layer are deposited on the glass substrate and on the first metal layer in order; the second metal layer is etched to form a data line; an isolation layer and an active layer are deposited on the first passivation layer and on the second metal layer in order; the active layer is etched simultaneously for reserving the active layer above the control electrode, and the active layer serves as a channel of the switch unit; the first passivation layer and the isolation layer above the data line are etched to form a via hole on top of the data line; a transparent conducting layer is deposited on the isolation layer, the data line, and the active layer; and the transparent conducting layer is etched to divide the transparent conducting layer into a first transparent conducting layer and a second transparent conducting layer, wherein the data line is electrically connected to the active layer through the first transparent conducting layer on the via hole, and the active layer is electrically connected to the second transparent conducting layer.

In yet another aspect of the present invention, a LCD panel comprises: a glass substrate; a first metal layer, disposed on the glass substrate, for functioning as a control electrode of a switch unit; a first passivation layer, disposed on the glass substrate and on the first metal layer; a second metal layer, disposed on the first passivation layer, for forming a data line; an isolation layer, disposed on the first passivation layer and the second metal layer; an active layer, disposed on the isolation layer, for functioning as a channel of the switch unit; a via hole, formed on top of the data line; and a transparent conducting layer, disposed on the isolation layer and on the via hole, comprising a first transparent conducting layer and a second transparent conducting layer, the first transparent conducting layer electrically connected to the data line, the second transparent conducting layer functioning as a pixel electrode. Upon receiving a scan voltage by the control electrode, a data voltage from the data line is transmitted to the second transparent conducting layer through the first transparent conducting layer and the active layer.

In yet another aspect of the present invention, a transistor formed on a glass substrate comprises: a metal layer disposed on the glass substrate for forming a gate of the transistor; a first passivation layer disposed on the first passivation layer and the glass substrate; an isolation layer, disposed on the metal layer; an active layer, disposed on the isolation layer, for functioning as a channel of the transistor; and a transparent conducting layer with an opening thereon to divide a first transparent conducting layer and a second transparent conducting layer. The first transparent conducting layer functions as a first electrode for inputting or outputting an electrical signal while the second transparent conducting layer functions as a second electrode for inputting or outputting the electrical signal.

In contrast to the prior art, the LCD panel and method for manufacturing the same of the present invention can produce LCD panels with a new TFT structure using a five-mask process. In the LCD panel, a transparent conducting layer forms a first electrode and a second electrode of a TFT directly. Meanwhile, the transparent conducting layer also serves as a connecting line between a TFT and a data line and between a TFT and an LC capacitor, without forming a via hole over the TFT to link the TFT and the transparent conducting layer. In this way, an area of a pixel electrode can be further extended, and the aperture rate of an LCD panel can be also increased, raising a transmittance of light from light sources passing through the pixel electrode.

These and other features, aspects and advantages of the present disclosure will become understood with reference to the following description, appended claims and accompanying figures.

### BRIEF DESCRIPTION OF THE DRAWINGS

FIG. 1 shows a schematic diagram of a pixel unit of a conventional LCD panel.

FIG. 2 is a cross section view along a line from point A to point B to point C in FIG. 1.

FIGS. 3 to 7 illustrate diagrams of the manufacturing process for completing the structure shown in FIG. 2.

FIGS. 8 to 16 illustrate schematic diagram of the LCD panel manufacturing process according to a first embodiment of the present invention.

FIG. 17 is a structure diagram of an LCD panel according to the present invention.

FIGS. 18 to 26 are schematic diagrams of the LCD panel manufacturing process according to a second embodiment of the present invention.

FIG. 27 is a structure diagram of an LCD panel according to the present invention.

FIG. 28 is a plan view of the LCD panel according to the first embodiment of the present invention.

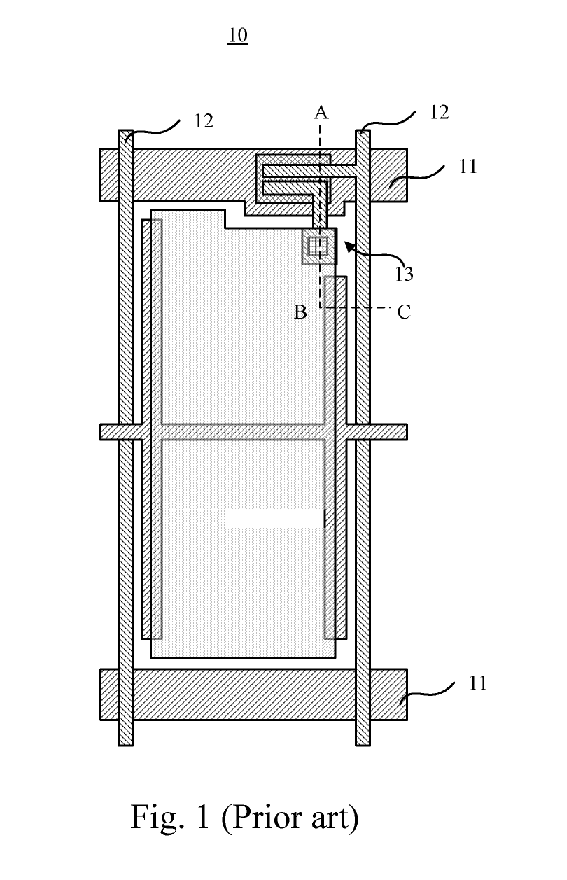

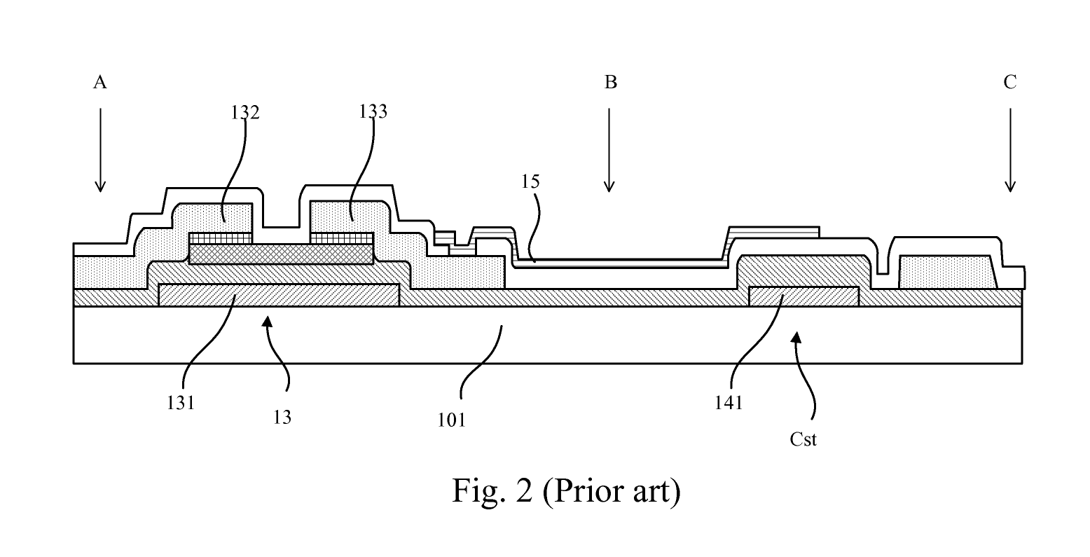

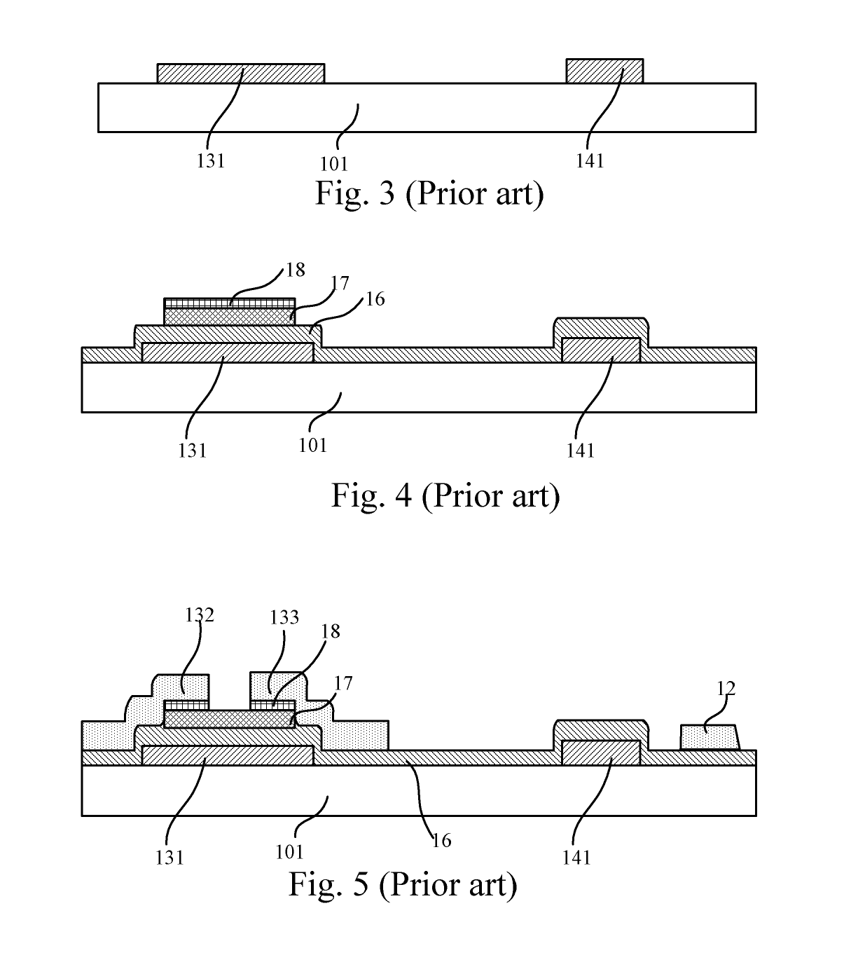

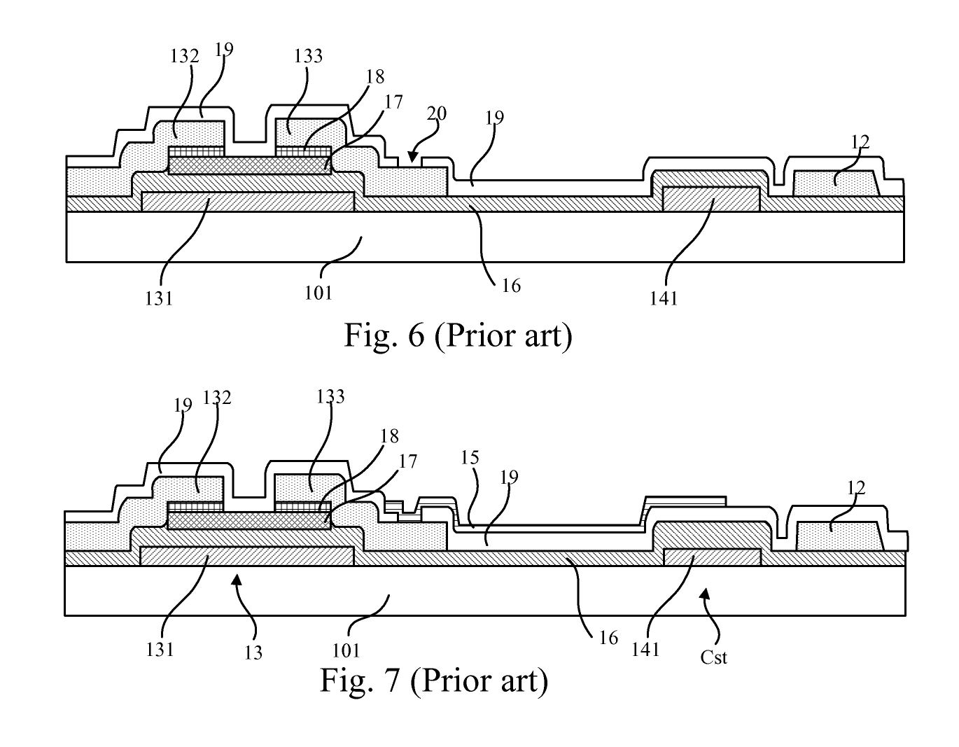

### DETAILED DESCRIPTION OF THE PREFERRED EMBODIMENTS

Spatially relative terms, such as “beneath”, “below”, “lower”, “above”, “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures.

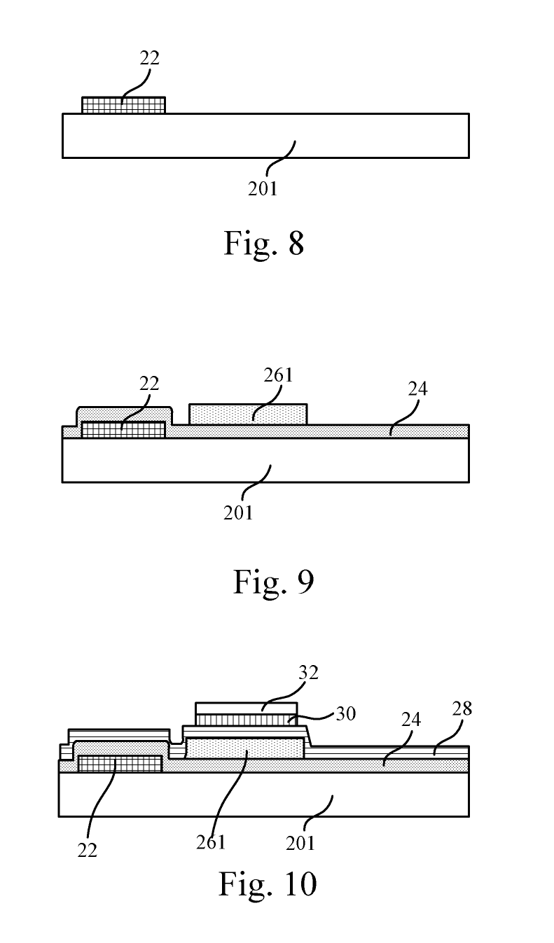

Refer to FIGS. 8 to 16, which illustrate schematic diagram of the LCD panel manufacturing process according to a first embodiment of the present invention. Firstly, refer to FIG. 8. During this stage of the manufacturing process, firstly, a first metal layer (not shown) is deposited on a glass substrate 201. Meanwhile, a developing process is conducted through a first mask. The developing process contains the following steps: coating a photoresist (not shown) on the first metal layer, exposing the photoresist through the first mask having a specific pattern, and then washing out the exposed photoresist with a developer. Afterwards, the first metal layer undergoes an etching process. The etching process includes the steps of: removing the first metal layer which is not covered by the photoresist with a strong acid, producing a data line 22 on the first metal layer covered by the photoresist (roughly showing the specific pattern), and washing out the remaining photoresist.

Refer to FIG. 9. During this stage of the manufacturing process, firstly, a first passivation layer 24 is deposited on the glass substrate 201 and the first metal layer. Next, a second metal layer (not shown) is deposited on the first passivation layer 24. Next, a developing process is conducted through a second mask. Meanwhile, the second metal layer undergoes an etching process in order to generate a control electrode 261.

Refer to FIG. 10. During this stage of the manufacturing process, firstly, an isolation layer 28 is deposited on the control electrode 261 and the first passivation layer 24. Next, an active layer and an ohmic contact layer are deposited on the isolation layer 28 in order. Subsequently, a developing process is conducted through a third mask. Meanwhile, the active layer 30 and the ohmic contact layer 32 undergo an etching process in order to reserve the active layer 30 and the ohmic contact layer 32 corresponding to the top of the control electrode 261.

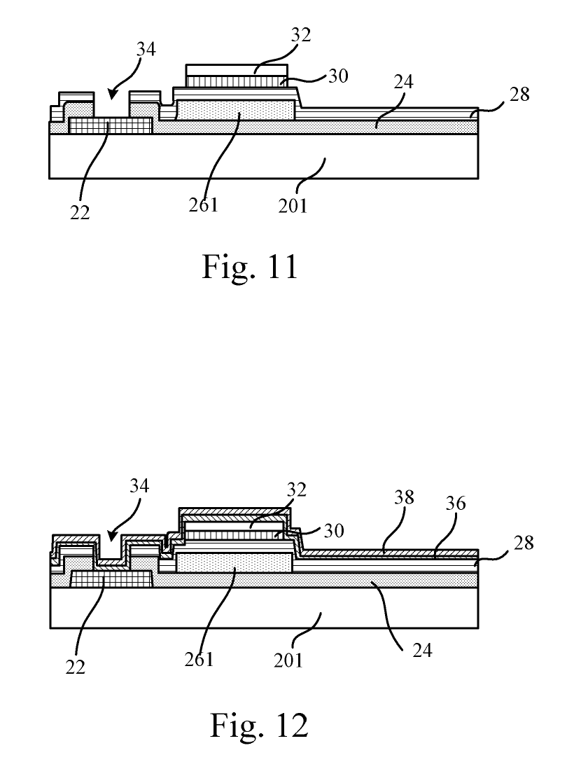

Refer to FIG. 11. During this stage of the manufacturing process, a developing process is conducted through a fourth mask. Meanwhile, the isolation layer 28 and the first passivation layer 24 undergo an etching process until the data line 22 is exposed and a via hole 34 is formed.

Refer to FIG. 12. During this stage of the manufacturing process, firstly, a transparent conducting layer 36 is deposited. Next, a layer of photoresist 38 is coated on top of the transparent conducting layer 36.

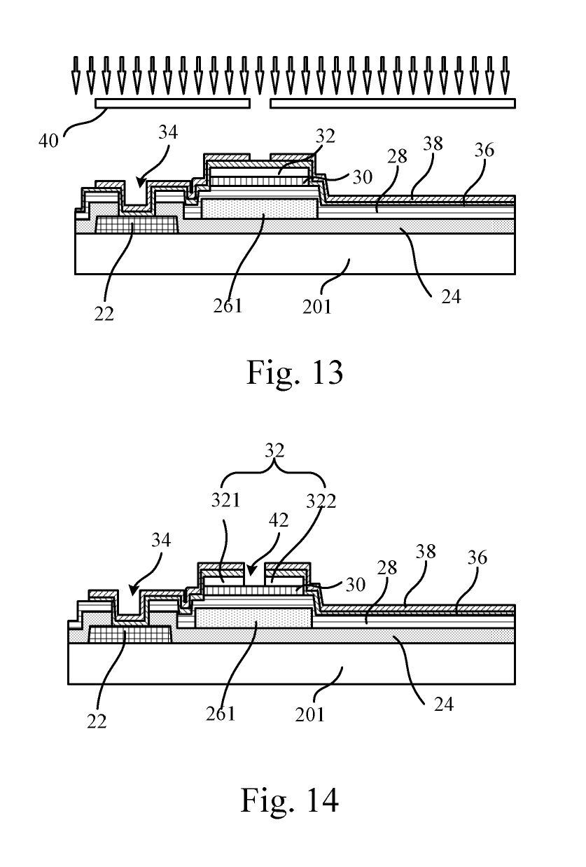

Refer to FIG. 13. During this stage of the manufacturing process, the photoresist 38 is exposed through a fifth mask 40. After the photoresist 38 is radiated by the ultraviolet light, part of photoresist 38 which is not covered by the fifth mask 40 changes its solubility to a developer. So the exposed photoresist 38 can be easily washed out with the developer.

Refer to FIG. 14. During this stage of the manufacturing process, part of the transparent conducting layer 36 and the ohmic contact layer 32, where the photoresist 38 does not cover, is removed by performing an etching process to form an opening 42. The opening 42 is formed on top of the control electrode 261. The ohmic contact layer 32 at both sides of the opening 42 forms a first ohmic contact layer 321 and a second ohmic contact layer 322, respectively.

Refer to FIG. 15. During this stage of the manufacturing process, a second passivation layer 44 is deposited on the remaining photoresist 38 and inside the opening 42 before the rest of photoresist 38 is removed.

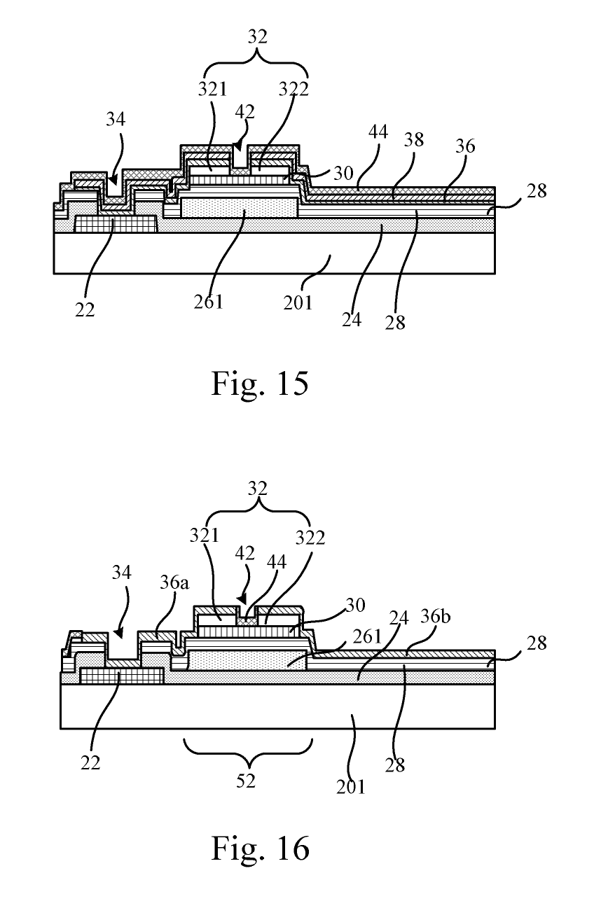

Refer to FIG. 16. During this stage of the manufacturing process, both of the photoresist 38 and the second passivation layer 44 deposited on the photoresist 38 are lifted off. The second passivation layer 44 inside the opening 42 is prevented from being lifted off because it does not adhere to the photoresist 38. Thus, the second passivation layer 44 adheres to the inner surface of the opening 42 and to the top of the active layer 30 corresponding to the opening 42.

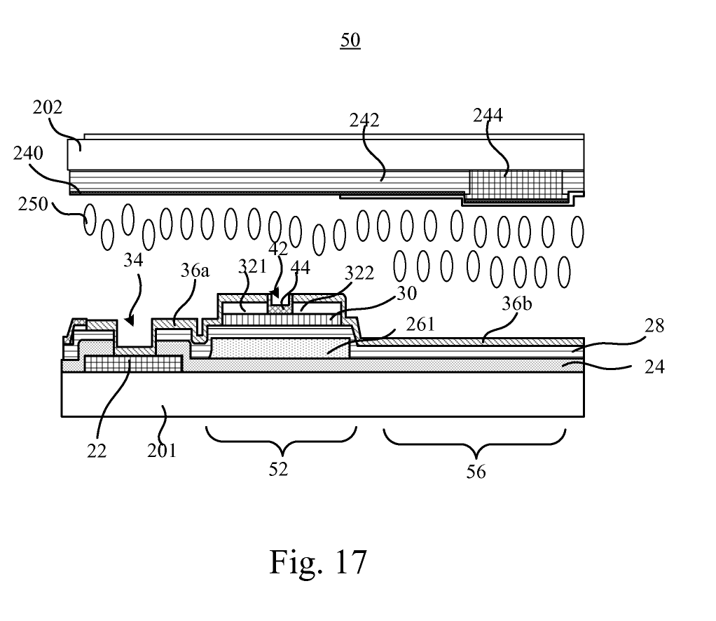

Refer to FIG. 17 and FIG. 28. FIG. 17 is a structure diagram of an LCD panel 50 according to the present invention. FIG. 28 is a plan view of the LCD panel according to the first embodiment of the present invention. The LCD panel 50 comprises a glass substrate 201 and a glass substrate 202. An LC layer 250 is injected onto the glass substrate 201 on which the data line 22 and the switch unit 52 are arranged, and then the glass substrate 202 having a black matrix 242 and a color filter 244 covers the LC layer 250. Another transparent electrode layer 240 covers the black matrix 242 and the color filter 244. A common voltage is applied to the transparent electrode layer 240 functioning as a common voltage electrode layer. The transparent conducting layer 36 is divided into a first transparent conducting layer 36a and a second transparent conducting layer 36b by the opening 42. The switch unit 52 can equivalently act as the TFT which controls data signals transmitted from the data line 22. In other words, the control electrode 261 of the switch unit 52 can act as a gate of the TFT. Practically, the first transparent conducting layer 36a and the second transparent conducting layer 36b serve as a first electrode and a second electrode of the switch unit 52, respectively. The first transparent conducting layer 36a and the second transparent conducting layer 36b can also serve as a source (a drain) of the TFT and a drain (a source) of the TFT, respectively. The active layer 30 serves as a channel between the drain of the switch unit 52 and the source of the switch unit 52. The first transparent conducting layer 36a, functioning as a first electrode, is capable of outputting or inputting electrical signals. Correspondingly, the second transparent conducting layer 36b, functioning as a second electrode, is capable of inputting or outputting electrical signals. An object of the second passivation layer 44 adhering to the opening 42 is to separate the ohmic contact layer 32 from the active layer 30 functioning as a channel, so that the active layer 30 and the ohmic contact layer 32 are prevented from approaching the LC layer 250 directly and further from affecting the alignment of LC molecules. According to this embodiment, the second transparent conducting layer 36b serves as not only a second electrode of the TFT 52 but also, practically, a pixel electrode. Practically, an LC capacitor 56 is formed by an overlap of the pixel electrode and the transparent conducting layer 240. Upon receiving a scanning voltage with the control electrode 52, a data voltage transmitted from the data line 22 is transmitted to the second transparent conducting layer 36b (i.e., the pixel electrode) through the first transparent conducting layer 36a and the switch unit 52. The alignment of the LC molecules of the LC layer 250 are adjusted according to a voltage difference between the data voltage applied on the second transparent conducting layer 36b and the common voltage applied on the transparent electrode layer 240, which decides the transmittance of light beams.

Refer to FIG. 16. The TFT 52 is formed on the glass substrate 201 according to the present embodiment. The TFT 52 comprises the first passivation layer 24 disposed on the glass substrate 201, the gate 261 disposed on the first passivation layer 24, the isolation layer 28 disposed on the gate 261, the active layer 30 disposed on the isolation layer 28 and functioning as a channel of the TFT 52, and the ohmic contact layer 32 disposed on the active layer 30 and having the opening 42. The ohmic contact layer 32 at both sides of the opening 42 forms the first ohmic contact layer 321 and the second ohmic contact layer 322, respectively. The transparent conducting layer 36 at both sides of the opening 42 forms the first transparent conducting layer 36a and the second transparent conducting layer 36b, respectively. The first transparent conducting layer 36a is connected to the first ohmic contact layer 321 and serves as the first electrode for outputting or inputting electrical signals. The second transparent conducting layer 36b is connected to the second ohmic contact layer 322 and serves as the second electrode for outputting or inputting electrical signals.

According to a preferred embodiment, the first ohmic contact layer 321 and the second ohmic contact layer 322 of the ohmic contact layer 32 is used for decreasing the resistance of the TFT 52. According to another embodiment, the ohmic contact layer 32 is unnecessary during the manufacturing process, so the first ohmic contact layer 321 and the second ohmic contact layer 322 are not necessary for the LCD panel 50 and the TFT 52.

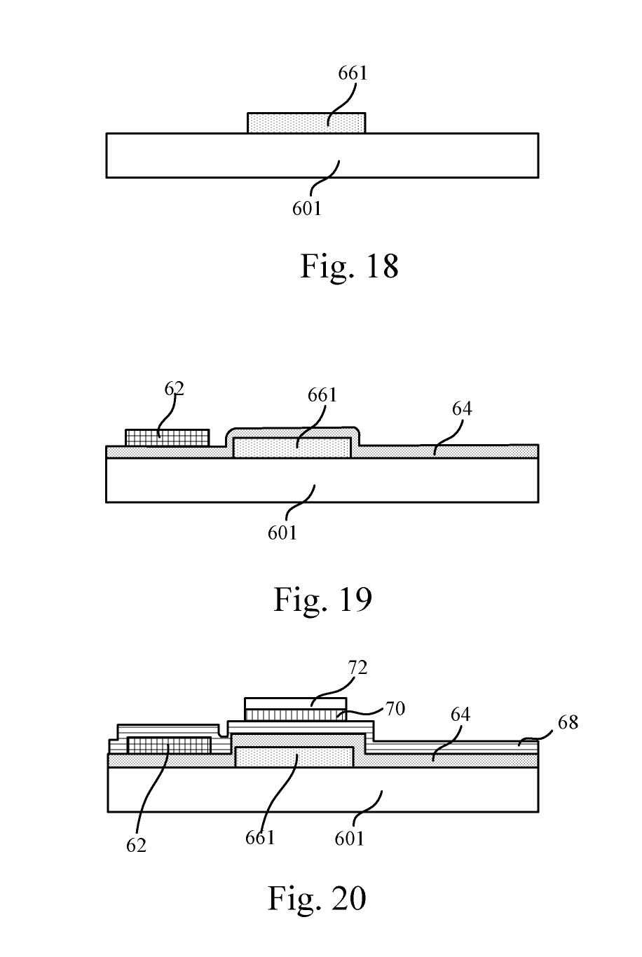

Refer to FIGS. 18 to 26, which are schematic diagrams of the LCD panel manufacturing process according to a second embodiment of the present invention. Firstly, refer to FIG. 18. During this stage of the manufacturing process, firstly, a first metal layer (not shown) is deposited on a glass substrate 601. Meanwhile, a developing process is conducted through a first mask. Afterwards, the first metal layer is etched to generate a control electrode 661 of a switch unit.

Refer to FIG. 19. During this stage of the manufacturing process, firstly, a first passivation layer 64 is deposited on the glass substrate 601 and the first metal layer. Next, a second metal layer (not shown) is deposited on the first passivation layer 64. Next, a developing process is conducted through a second mask. Meanwhile, the second metal layer undergoes an etching process in order to generate a data line 62.

Refer to FIG. 20. During this stage of the manufacturing process, firstly, an isolation layer 68 is deposited on the control electrode 661 and the first passivation layer 64. Next, an active layer and an ohmic contact layer are deposited on the isolation layer 68 in order. Subsequently, a developing process is conducted through a third mask. Meanwhile, the active layer and the ohmic contact layer undergo an etching process in order to reserve the active layer 70 and the ohmic contact layer 72 corresponding to the top of the control electrode 661.

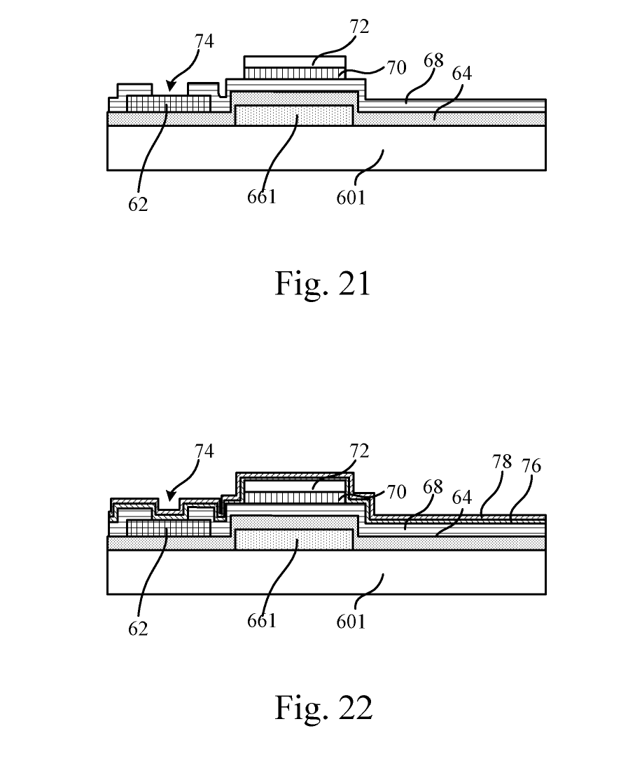

Refer to FIG. 21. During this stage of the manufacturing process, a developing process is conducted through a fourth mask. Meanwhile, the isolation layer 68 undergo an etching process until the data line 62 is exposed and a via hole 74 is formed.

Refer to FIG. 22. During this stage of the manufacturing process, firstly, a transparent conducting layer 76 is deposited. Next, a layer of photoresist 78 is coated on top of the transparent conducting layer 76.

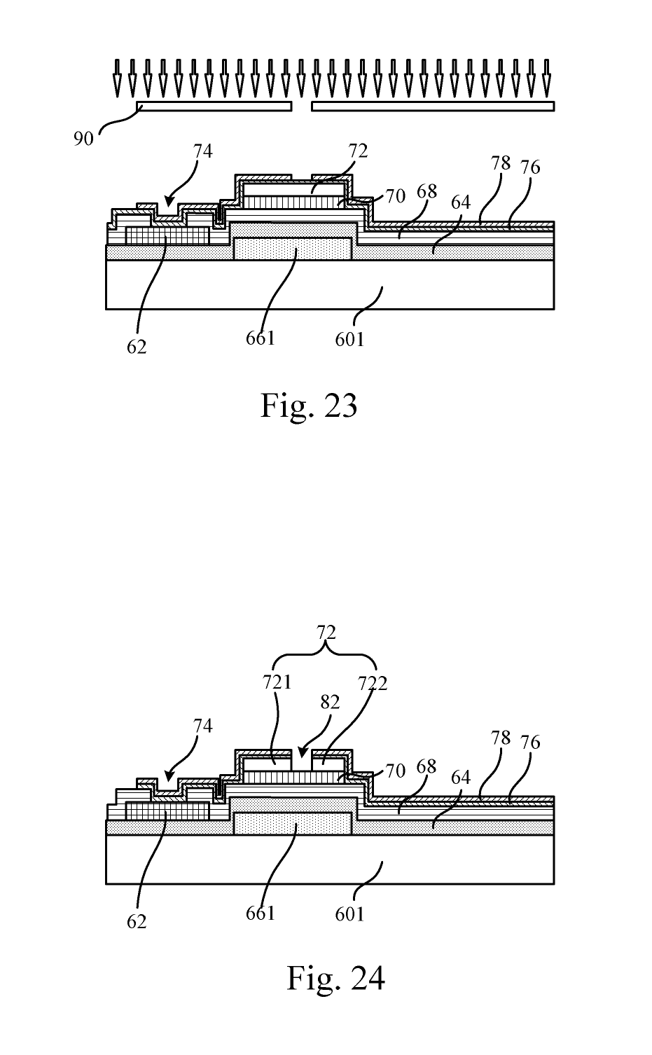

Refer to FIG. 23. During this stage of the manufacturing process, the photoresist 78 is exposed through a fifth mask 90. After the photoresist 78 is radiated by the ultraviolet light, part of photoresist 78 which is not covered by the fifth mask 90 changes its solubility to a developer. So the exposed photoresist 78 can be easily washed out with the developer.

Refer to FIG. 24. During this stage of the manufacturing process, part of the transparent conducting layer 76 and the ohmic contact layer 72, which is not shielded by the non-exposed photoresist 78, is removed by performing an etching process to form an opening 82. The opening 82 is formed on top of the control electrode 661. The ohmic contact layer 72 at both sides of the opening 82 forms a first ohmic contact layer 721 and a second ohmic contact layer 722, respectively.

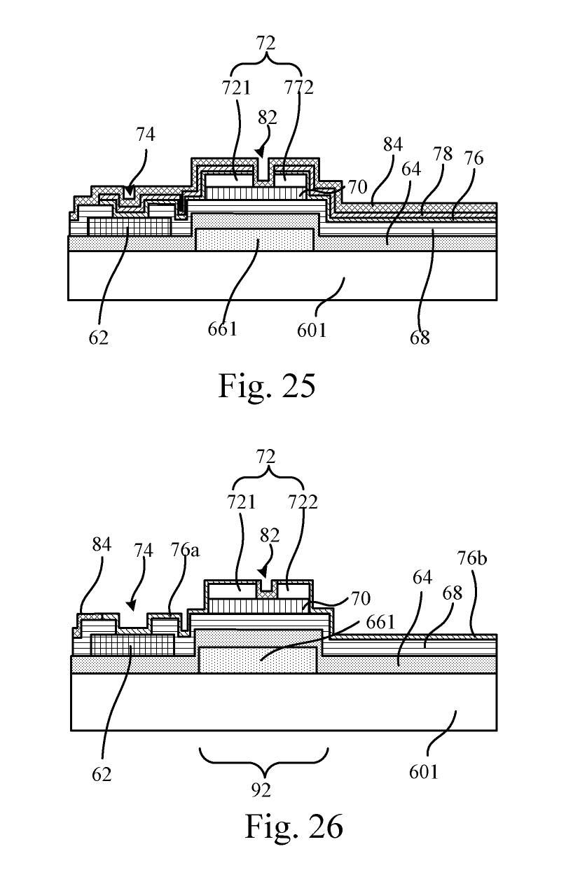

Refer to FIG. 25. During this stage of the manufacturing process, a second passivation layer 84 is deposited on the remaining photoresist 78 and inside the opening 82 before the remaining photoresist 78 is removed.

Refer to FIG. 26. During this stage of the manufacturing process, both of the photoresist 78 and the second passivation layer 84 deposited on the photoresist 78 are lifted off. The second passivation layer 84 inside the opening 82 is prevented from being lifted off because it does not adhere to the photoresist 78. Thus, the second passivation layer 84 adheres to the inner surface of the opening 82 and to the top of the active layer 70 corresponding to the opening 82, for isolating the active layer 70 from liquid crystal molecules.

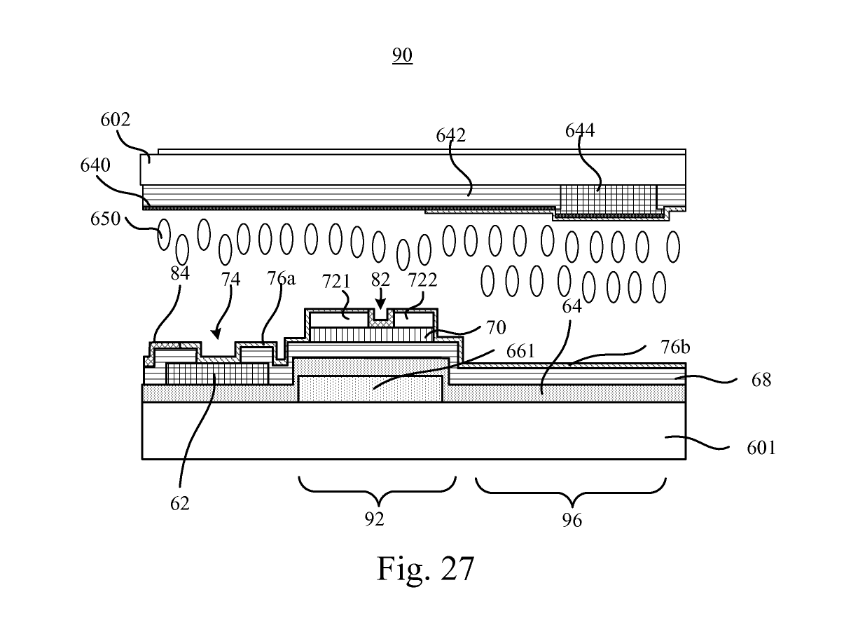

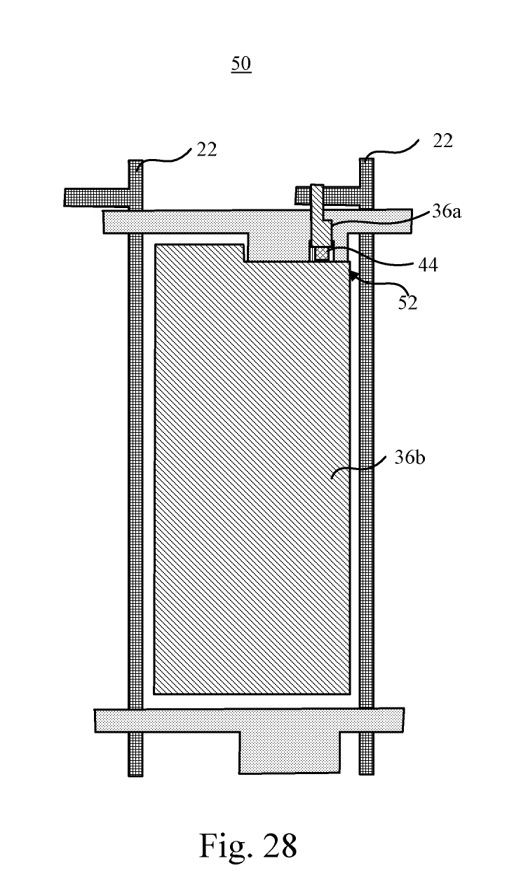

Refer to FIG. 27, which is a structure diagram of an LCD panel 90 according to the present invention. The LCD panel 90 comprises a glass substrate 601 and a glass substrate 602. An

LC layer 650 is injected on the glass substrate 601 on which the data line 62 and the switch unit 92 are arranged, and then the glass substrate 602 having a black matrix 642 and a color filter 644 covers the LC layer 650. Another transparent electrode layer 640 covers the black matrix 642 and the color filter 644. A common voltage is applied to the transparent electrode layer 640 functioning as a common voltage electrode layer. The transparent conducting layer 76 is divided into a first transparent conducting layer 76a and a second transparent conducting layer 76b by the opening 82. The switch unit 92 can equivalently act as the TFT which controls data signals transmitted from the data line 62. In other words, the control electrode 661 of the switch unit 92 can act as a gate of the TFT. Practically, the first transparent conducting layer 76a and the second transparent conducting layer 76b serve as a first electrode and a second electrode of the switch unit 92, respectively. The first transparent conducting layer 76a and the second transparent conducting layer 76b can also serve as a source (a drain) of the TFT and a drain (a source) of the TFT, respectively. The active layer 70 serves as a channel between the drain of the switch unit 92 and the source of the switch unit 92. The first transparent conducting layer 76a, functioning as a first electrode, is capable of outputting or inputting electrical signals. Correspondingly, the second transparent conducting layer 76b, functioning as a second electrode, is capable of outputting or inputting electrical signals. An object of the second passivation layer 84 adhering to the opening 82 is to separate the ohmic contact layer 72 from the active layer 70 functioning as the channel, so that the active layer 70 and the ohmic contact layer 72 are prevented from approaching the LC layer 650 directly and further from affecting the alignment of LC molecules. According to this embodiment, the second transparent conducting layer 76b serves as not only a second electrode of the TFT 92 but also, practically, a pixel electrode. Practically, an LC capacitor 96 is formed by an overlap of the pixel electrode and the transparent conducting layer 640. Upon receiving a scanning voltage with the control electrode 661, a data voltage transmitted from the data line 62 is transmitted to the second transparent conducting layer 76b (i.e., the pixel electrode) through the first transparent conducting layer 76a and the switch unit 92. The alignment of the LC molecules of the LC layer 650 are adjusted according to a voltage difference between the data voltage applied on the second transparent conducting layer 76b and the common voltage applied on the transparent electrode layer 640, which decides the transmittance of light beams.

Refer to FIG. 26. The TFT 92 is formed on the glass substrate 601 according to the present embodiment. The TFT 92 comprises the first passivation layer 64 disposed on the glass substrate 601, the gate 661 disposed on the first passivation layer 64, the isolation layer 68 disposed on the gate 661, the active layer 70 disposed on the isolation layer 68 and functioning as a channel of the TFT 92, and the ohmic contact layer 72 disposed on the active layer 70 and having the opening 82. The ohmic contact layer 72 at both sides of the opening 82 forms the first ohmic contact layer 721 and the second ohmic contact layer 722, respectively. The transparent conducting layer 76 at both sides of the opening 82 forms the first transparent conducting layer 76a and the second transparent conducting layer 76b, respectively. The first transparent conducting layer 76a is connected to the first ohmic contact layer 721 and serves as the first electrode for outputting or inputting electrical signals. The second transparent conducting layer 76b is connected to the second ohmic contact layer 722 and serves as the second electrode for outputting or inputting electrical signals.

According to a preferred embodiment, the first ohmic contact layer 721 and the second ohmic contact layer 722 of the ohmic contact layer 72 is used for decreasing the resistance of the TFT 92. According to another embodiment, the ohmic contact layer 72 is unnecessary during the manufacturing process, so the first ohmic contact layer 721 and the second ohmic contact layer 722 are not necessary for the LCD panel 90 and the TFT 92.

Although the present invention has been explained by the embodiments shown in the drawings described above, it should be understood to the ordinary skilled person in the art that the invention is not limited to the embodiments, but rather various changes or modifications thereof are possible without departing from the spirit of the invention. Accordingly, the scope of the invention shall be determined only by the appended claims and their equivalents.

What is claimed is:

1. A method of forming a liquid crystal display panel, characterized in that:
a glass substrate is provided;
a first metal layer formed on the glass substrate is etched to form a control electrode of a switch unit;
a first passivation layer and a second metal layer are deposited on the glass substrate and on the first metal layer in order;
the second metal layer is etched to form a data line;
an isolation layer and an active layer are deposited on the first passivation layer and on the second metal layer in order;
the active layer is etched simultaneously for reserving the active layer above the control electrode, and the active layer serves as a channel of the switch unit;
the first passivation layer and the isolation layer above the data line are etched to form a via hole on top of the data line;
a transparent conducting layer is deposited on the isolation layer, the data line, and the active layer; and
the transparent conducting layer is etched to divide the transparent conducting layer into a first transparent conducting layer and a second transparent conducting layer, wherein the data line is electrically connected to the active layer through the first transparent conducting layer on the via hole, and the active layer is electrically connected to the second transparent conducting layer.

2. The method as claimed in claim 1, characterized in that:
the isolation layer, the active layer, and an ohmic contact layer are deposited on the first passivation layer and on the second metal layer in order;
the active layer and the ohmic contact layer are etched simultaneously for reserving the active layer and the ohmic contact layer on top of the control electrode, and the active layer serves as the channel of the switch unit;
the first passivation layer and the isolation layer on the data line are etched for forming a via hole on top of the data line;
the transparent conducting layer is deposited on the isolation layer, the data line, and the ohmic contact layer; and
the transparent conducting layer and the ohmic contact layer are etched for dividing the transparent conducting layer into a first transparent conducting layer and a second transparent conducting layer and for dividing the ohmic contact layer into a first ohmic contact layer and a second ohmic contact layer, wherein the data line passes through the first transparent conducting layer on the via hole, the first ohmic contact layer is disposed between the first transparent conducting layer and the active layer, and the second ohmic contact layer is disposed between the second transparent conducting layer and the active layer.

3. The method as claimed in claim 1, characterized in that the step of etching the transparent conducting layer further comprises:
a photoresist is deposited on top of the transparent conducting layer; and
the photoresist is exposed and developed, and the transparent conducting layer is etched for forming an opening over the active layer.

4. The method as claimed in claim 2, characterized in that the step of etching the transparent conducting layer further comprises:
a photoresist is deposited on top of the transparent conducting layer; and
the photoresist is exposed and developed, and the transparent conducting layer is etched for forming an opening over the active layer.

5. The method as claimed in claim 3, characterized in that the step of etching the transparent conducting layer further comprises:
a second passivation layer is deposited on the photoresist, the isolation layer, and the opening; and
the photoresist and the second passivation layer on the photoresist are lifted off, so that the second passivation layer which is not lifted off covers the transparent conducting layer.

6. The method as claimed in claim 4, characterized in that the step of etching the transparent conducting layer further comprises:
a second passivation layer is deposited on the photoresist, the isolation layer, and the opening; and
the photoresist and the second passivation layer on the photoresist are lifted off, so that the second passivation layer which is not lifted off covers the transparent conducting layer.
